(19) United States
(12) Patent Application Publication
(10) Pub. No.: US 2024/0162329 A1
(43) Pub. Date: May 16, 2024

(54) MANUFACTURING METHOD

(71) Applicant: STMicroelectronics (Crolles 2) SAS, Crolles (FR)

(72) Inventors: Alexis GAUTHIER, Meylan (FR); Pascal CHEVALIER, Chapareillan (FR); Edoardo BREZZA, Grenoble (FR); Nicolas GUITARD, Allevard (FR)

(73) Assignee: STMicroelectronics (Crolles 2) SAS, Crolles (FR)

(21) Appl. No.: 18/387,325

(22) Filed: Nov. 6, 2023

(30) Foreign Application Priority Data
Nov. 10, 2022 (FR) 2211714

(51) Int. Cl. H01L 29/66; H01L 29/08; H01L 29/10; H01L 29/737

(52) U.S. Cl. CPC H01L 29/66242; H01L 29/0817; H01L 29/1004; H01L 29/6653; H01L 29/66553; H01L 29/6656; H01L 29/737

(57) ABSTRACT

An electronic device includes an insulating first layer covering a second layer made of a doped semiconductor material. A cavity is formed to cross through the first layer and reach the second layer. Insulating spacers are forming against lateral walls of the cavity. A first doped semiconductor region fills the cavity. The first doped semiconductor region has a doping concentration decreasing from the second layer.

### PRIORITY CLAIM

This application claims the priority benefit of French Application for Patent No. 2211714, filed on Nov. 10, 2022, the content of which is hereby incorporated by reference in its entirety to the maximum extent allowable by law.

### TECHNICAL FIELD

The present disclosure generally concerns electronic devices and, in particular, to electronic devices comprising doped regions and their manufacturing methods.

### BACKGROUND

A bipolar transistor is an electronic device based on a semiconductor of the family of transistors. Its operating principle is based on two PN junctions, one forward and the other reverse. The biasing of the reverse PN junction with a low electric current (sometimes called transistor effect) enables to “control” a much higher current, according to the current amplification principle.

The operation of bipolar transistors depends on a large number of characteristics of bipolar transistors. Such a characteristic of bipolar transistors is their maximum oscillation frequency.

There is a need in the art to overcome all or part of the disadvantages of known semiconductor region manufacturing methods.

### SUMMARY

An embodiment provides an electronic device comprising an insulating first layer covering a second layer made of a doped semiconductor material, a cavity crossing the insulating first layer, spacers being located against the lateral walls of the cavity, the cavity comprising a doped first semiconductor region, the doped first semiconductor region having a doping concentration decreasing from the second layer.

According to an embodiment, the second layer and the doped first semiconductor region form part of a collector of a bipolar transistor.

Another embodiment provides a method of manufacturing an electronic device comprising: forming an insulating first layer covering a second layer made of a doped semiconductor material; forming a cavity crossing the first layer; forming spacers against lateral walls of the cavity; and epitaxially growing a first doped semiconductor region in the cavity, from the second layer, the first doped semiconductor region having a doping concentration decreasing from the second layer.

According to an embodiment, a portion of the collector of the transistor is manufactured by the previously-described method, the second layer and the first doped semiconductor region forming part of the collector.

According to an embodiment, the spacers have a profile decreasing from the first layer.

According to an embodiment, the spacers and the first doped semiconductor region fill the cavity.

According to an embodiment, the first doped semiconductor region comprises a first surface in contact with the second layer, and a second surface opposite to the first surface, the surface area of the second surface being greater than the surface area of the first surface.

According to an embodiment, the surface area of the second surface of the first region is twice greater than the surface area of the first surface of the first doped semiconductor region.

According to an embodiment, the method comprises forming the second layer in a semiconductor substrate, forming an insulating third layer covering the second layer, and forming a second doped semiconductor region forming part of the collector of the transistor flush with the upper surface of the substrate.

According to an embodiment, the method comprises etching to expose the upper surface of the second doped semiconductor region.

According to an embodiment, a stack of layers is formed on the substrate, the stack comprising an insulating fourth layer covering the third layer, a fifth layer made of the material of the base, and an insulating sixth layer, the third and fourth layers forming the first layer.

According to an embodiment, the cavity crosses the stack and the third layer to expose the second layer.

According to an embodiment, the spacers are formed in such a way as to at least partially cover the lateral walls of the fifth layer, the method comprising partially etching the spacers in such a way that the upper surface of the spacers is coplanar with the upper surface of the first layer.

According to an embodiment, the method comprises forming a seventh layer, forming part of the base of the transistor, the seventh layer covering the first doped semiconductor region.

According to an embodiment, the method comprises forming the emitter region in front of the first doped semiconductor region, separated from the first doped semiconductor region by the seventh layer.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an embodiment of a doped region;

FIG. 2A shows a device resulting from a step of a method of manufacturing the embodiment of FIG. 1;

FIG. 2B shows a device resulting from another step of a method of manufacturing the embodiment of FIG. 1;

FIG. 2C shows a device resulting from another step of a method of manufacturing the embodiment of FIG. 1;

FIG. 3 shows an embodiment of a bipolar transistor;

FIG. 4A shows a device resulting from a step of a method of manufacturing the embodiment of FIG. 3;

FIG. 4B shows a device resulting from another step of a method of manufacturing the embodiment of FIG. 3;

FIG. 4C shows a device resulting from another step of a method of manufacturing the embodiment of FIG. 3;

FIG. 4D shows a device resulting from another step of a method of manufacturing the embodiment of FIG. 3;

FIG. 4E shows a device resulting from another step of a method of manufacturing the embodiment of FIG. 3;

FIG. 4F shows a device resulting from another step of a method of manufacturing the embodiment of FIG. 3;

FIG. 4G shows a device resulting from another step of a method of manufacturing the embodiment of FIG. 3;

FIG. 4H shows a device resulting from another step of a method of manufacturing the embodiment of FIG. 3; and

FIG. 4I shows a device resulting from another step of a method of manufacturing the embodiment of FIG. 3.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

Unless specified otherwise, the expressions “insulating” or “conductive” signify “electrically-insulating” or “electrically-conductive”.

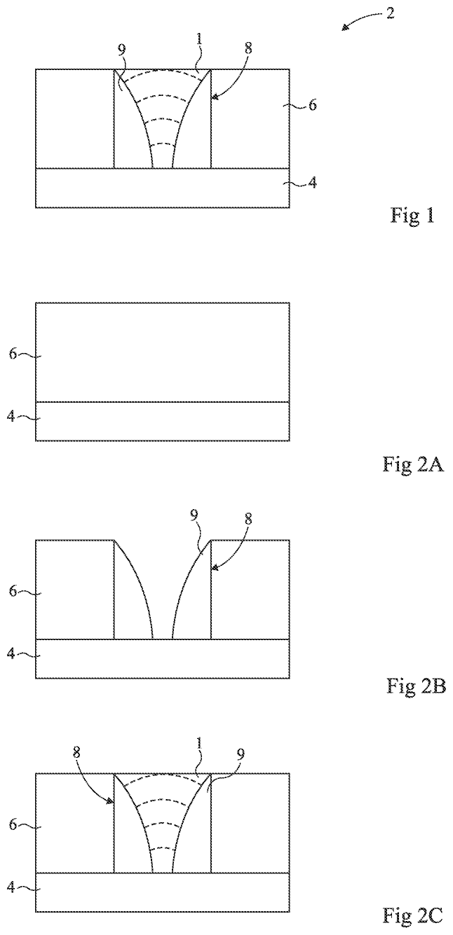

FIG. 1 shows an embodiment of a doped region 1 in a device 2.

Device 2 comprises a layer 4 made of doped semiconductor material. Layer 4 is, for example, made of doped silicon, for example, of N-type doped silicon. The upper surface of layer 4 is preferably planar.

Layer 4 is covered with a layer 6 made of an insulating material. Layer 6 is, for example, made of silicon oxide. A cavity 8 is located in layer 6. Cavity 8 crosses through layer 6 to expose layer 4. In other words, cavity 8 extends from the level of the upper surface of layer 6, that is, the surface of layer 6 most distant from layer 4, to the upper surface of layer 4, that is, the surface of layer 4 closest to layer 6. Preferably, cavity 8 does not extend into layer 4. Thus, the bottom of cavity comprises, preferably exclusively, a portion of the upper surface of layer 4. The lateral walls of cavity 8 comprise, preferably exclusively, portions of layer 6.

Spacers 9, referred to as “inner” spacers, are located against the lateral walls of cavity 8. Spacers 9 preferably cover all of the lateral walls of cavity 8. Spacers 9 extend from the upper surface of layer 4, preferably up to the level of the upper surface of layer 6. Further, spacers 9 cover the periphery of the upper surface of layer 4. Thus, the peripheral portion, that is, the closest to the lateral walls of cavity 8, from the bottom of cavity 8, is entirely covered with spacers 9. A central portion of the bottom of cavity 8 is not covered with spacers 9.

Spacers 9 have a profile decreasing in width from the upper surface of layer 4. In other words, the larger the distance to layer 4, the lower the distance between the lateral wall of cavity 8 and region 1, that is, the width of the spacers. Thus, the width of the spacers is the lowest at the level of the upper surface of region 1 and is the stronger at the level of the lower face of region 1.

Region 1 is located in cavity 8. Region 1 fills, for example, cavity 8. Region 1 covers, and is in contact with, the central portion of the bottom of cavity 8, that is, the portion of the upper surface of layer 4 forming the bottom of the cavity. Region 1 covers, and is preferably in contact with, spacers 9. Region 1 preferably extends from the upper surface of layer 4 up to the level of the upper surface of layer 6.

Due to the decreasing profile of spacers 9 from the upper surface of layer 4, region 1 has a profile increasing in area from the upper surface of layer 4. In other words, the more the distance to the upper surface of layer 4 increases, the more the surface area of region 1 increases. In other words, region 1 comprises a first surface in contact with layer 4, and a second surface opposite to the first surface, the surface area of the second surface being greater than the surface area of the first surface. For example, the surface area of the second surface is twice greater than the surface area of the first surface.

Region 1 is made of the same material as layer 4. Region 1 is doped with the same doping type as layer 4. For example, region 1 and layer 4 are N-type doped. More precisely, region 1 and layer 4 are doped with the same dopants.

The doping, that is, the dopant concentration, of region 1 forms a gradient from layer 4. More precisely, the doping of region 1 forms a decreasing gradient from layer 4. The larger the distance to the portion of layer 4 in contact with region 1, the lower the doping. The doping gradient is schematically shown by dotted lines, indicating various portions of region 1, each portion corresponding to a range, preferably continuous, of dopant concentration, preferably distinct from the ranges corresponding to the portions. The more the portion is distant from layer 4, the more the range of values comprises low values. Thus, the peripheral region of the upper surface of region 1 has the lowest doping.

FIGS. 2A, 2B, and 2C show steps, for example successive, of a method of manufacturing a doped region such as that shown in FIG. 1.

FIG. 2A shows a device resulting from a step of a method of manufacturing the embodiment of FIG. 1.

During this step, layer 6 is formed above layer 4. Layer 6 preferably covers the entire layer 4. Layer 6 covers at least the location of cavity 8 and the contour of the location of cavity 8.

The doping of layer 4 is preferably substantially equal, or greater than, the doping of the layer 4 of FIG. 1.

FIG. 2B shows a device resulting from another step of a method of manufacturing the embodiment of FIG. 1.

During this step, cavity 8 is formed in layer 6. For example, cavity 8 is formed by the etching of layer 6 at the location of cavity 8 to extend through layer 6 and reach layer 4.

The step of FIG. 2B further comprises the forming of spacers 9. The forming of spacers 9 comprises, for example, the forming, conformally, of a layer made of the material of the spacers, for example over the entire structure resulting from the forming of cavity 8. Said layer is then etched by an anisotropic etching, to only keep spacers 9.

FIG. 2C shows a device resulting from another step of a method of manufacturing the embodiment of FIG. 1.

The step of FIG. 2C comprises the epitaxial growth of region 1 from layer 4, more precisely from the portion of the upper surface of layer 4 forming the bottom of cavity 8 and which is not covered with spacers.

The increasing profile of region 1 from layer 4 causes the decrease of the concentration with the increase of the distance to layer 4 comprising the dopants. The doping of region 1 thus forms a gradient.

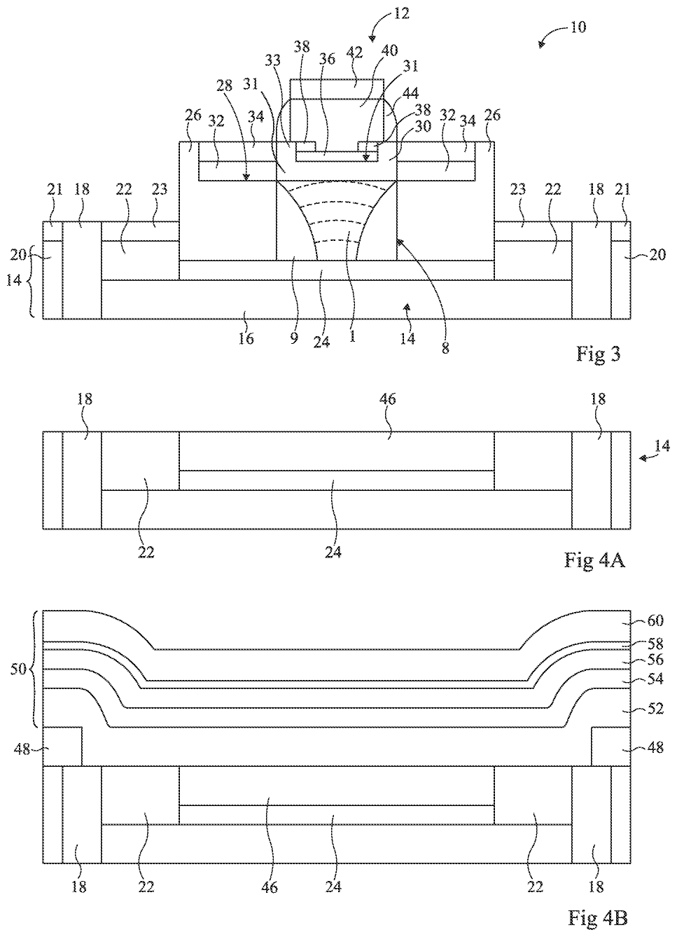

FIG. 3 shows an embodiment of an electronic device 10 comprising a bipolar transistor 12.

Bipolar transistor 12 is formed in a substrate 14. More precisely, transistor 12 is formed in the substrate and on an upper surface of substrate 14. The substrate is made of a semiconductor material, for example of silicon. Transistor 12 comprises a region 16 of substrate 14. Region 16 is a buried region of substrate 14. In other words, region 16 does not extend all the way to the upper surface of substrate 14. Region 16, preferably, is not doped.

Transistor 12 further comprises an insulating wall 18. Wall 16 is made of an electrically-insulating material, for example of silicon oxide. Wall 16 extends in substrate 14, for example from the upper surface. For example, wall 18 laterally surrounds region 16. As a variant, the transistor may comprise a plurality of walls 18, walls 18 laterally delimiting region 16 on at least certain sides.

Device 10 further comprises regions 20 of substrate 14. Regions 20 are made of a material identical to region 16. Preferably, regions 20 have the same doping as region 16. For example, regions 20 are not doped. Regions 20 are partially separated from region 16 by wall(s) 18. Regions 20 are physically and electrically coupled to region 16 under wall 18. Thus, the biasing of region 20 causes the biasing of region 16.

Device 10 comprises a conductive layer 21. Layer 21 covers, preferably entirely, preferably only, the upper surface of region 20. Layer 21 is made of an electrically-conductive material, for example of a metal. Layer 21 corresponds to the contact of the substrate of transistor 12, for example enabling to bias regions 20 and region 16.

Transistor 12 further comprises a region 22 in substrate 14. Region 22 is located inside of wall 18. Region 22 extends from the upper surface of substrate 14 to region 16. Region 22 preferably extends along the lateral inner surface of wall 18. Region 22 is thus preferably in contact with wall 18.

Region 22 is made of the semiconductor material of substrate 14, for example of silicon. Region 22 is doped with a first conductivity type, preferably n-type doped. Region 22 corresponds to a portion of transistor 12.

Transistor 12 comprises a conductive layer 23. Layer 23 covers, preferably entirely, preferably only, the upper surface of region 22. Layer 23 is made of an electrically-conductive material, for example of a metal. Layer 23 corresponds to the contact of the collector of transistor 12.

Region 22 laterally surrounds a portion of a region 24 of transistor 12. Region 24 is located inside of wall 18 and inside of region 22. Region 24 extends from the upper surface of region 16 and up to the upper surface of substrate 14. Region 24 preferably extends along the lateral inner surface of region 22. Region 22 is thus preferably in contact with region 24. Region 24 extends in a plane parallel to the upper surface of region 16. Region 24 is preferably a layer having a substantially constant thickness. The upper surface of region 24 is preferably planar. Region 24 extends in the entire area surrounded with region 22. Region 24 extends over region 16. The first portion is thus in contact with region 16 and with region 22.

Region 24 is made of the semiconductor material of substrate 14 and of region 22, for example made of silicon. Region 24 is doped with the same conductivity type as region 22, for example of the first conductivity type, preferably n-type doped. Region 24 corresponds to another portion of the collector of transistor 12.

Preferably, region 24 has a doping level, that is, a dopant concentration of the first type, smaller than the doping level, that is, than the dopant concentration, of region 22.

Transistor 12 comprises a region 26. Region 26 is made of an electrically-insulating material, for example silicon oxide. Region 26 extends over region 24. Region 26 extends from the upper surface of region 24 up to a level higher than the level of the upper surface of layer 23. Region 26 preferably extends over the entire periphery of region 24, to form a cavity 8 substantially in front of the center of region 24. Region 26 is thus preferably in contact with the lateral walls of layers 23 and of regions 22. A portion of the upper surface of region 24 thus forms the bottom of cavity 8.

Spacers 9 and region 1, such as described in relation with FIG. 1, are located in cavity 8. Region 24 then corresponds to the layer 4 of FIG. 1. Region 1 is thus doped with the same doping type as region 24, that is, type N. Regions 1, 24, and 22 thus form the collector of transistor 12.

The upper surface of region 24 is preferably entirely covered with region 1, with spacers 9, and with region 26.

Region 26 extends, on the external side, that is, the side most distant from region 1, along a height greater than on the inner side. Region 26 thus forms, at the level of its upper surface, a step. The assembly comprising region 26 and region 1 thus comprises a cavity 28, laterally delimited by region 26, and more precisely the portion of region 26 having a height greater than the rest of region 26. The bottom of cavity 28 is formed by region 26, and more precisely by the portion of region 26 having the lowest height, and by the upper surface of region 1.

Transistor 12 further comprises a region 30. Region 30 is located in cavity 28. Region 30 is, for example, located, preferably entirely, in front of cavity 8. Region 30 preferably comprises a first portion 31 corresponding to a layer and a second portion 33 extending from first portion 31 to form a cavity 31 in region 30. The bottom of cavity 31 is formed by the first portion of region 30 and the lateral walls of cavity 31 are formed by the second portion 33 of region 30.

Region 30 covers, preferably entirely, the upper surface of region 1. Region 30 does not, for example, cover the upper surface of region 26. Region 30 is preferably located at the center of cavity 28. The portion of the bottom of cavity 28 covered with region 30 is surrounded with a portion of the bottom of cavity 28 which is not covered with region 30.

Region 30 is, for example, made of the semiconductor material of substrate 14, for example of silicon. Region 30 is doped with a second conductivity type, that is, the conductivity type opposite to the first conductivity type, preferably p-type doped. Region 30 corresponds to a portion of the base of transistor 12.

Transistor 12 comprises a region 32 located in cavity 28. Region 32 covers the bottom of cavity 28 which is not covered with region 30. Thus, region 32 laterally surrounds the first portion of region 30. The bottom of cavity 38 is thus preferably entirely covered with regions 30 and 32. Region 32 preferably does not cover the upper surface of region 1. Region 32 has, for example, the same height as the first portion of region 30.

Region 32 is, for example, made of polysilicon. Region 32 is doped with the same conductivity type as region 30, that is, the second conductivity type, that is, the conductivity type opposite to the first conductivity type, preferably p-type doped. Region 32 corresponds to a portion of the base of transistor 12. Regions 30 and 32 thus form the base of transistor 12.

Preferably, region 30 has a doping level, that is, a dopant concentration of the second type, lower than the doping level, that is, than the dopant concentration, of region 32.

Transistor 12 comprises a conductive layer 34. Layer 34 covers, preferably entirely, preferably only, the upper surface of region 32. Layer 24 is made of an electrically-conductive material, for example of a metal. Layer 34 corresponds to the contact of the base of transistor 12.

Transistor 12 further comprises a layer 36 located in cavity 31. In other words, layer 36 covers, preferably entirely, the bottom of cavity 31. In other words, layer 36 extends over the first portion of region 30, laterally surrounded with the second portion 33 of region 30. The height of layer 36 is preferably smaller than the height of portion 33. Layer 36 is, for example, made of the same material as substrate 14, for example of silicon. The material of layer 36 is preferably not doped.

Transistor 12 comprises an insulating layer 38. Layer 38 is, for example, made of silicon oxide. Layer 38 extends over a portion of layer 36. Layer 38 extends over the periphery of layer 36. Layer 38 is preferably in contact with portion 33 over the entire contour of cavity 31 and extends towards the center of layer 36. Layer 38 does not entirely cover layer 36. A central portion of layer 36 is not covered with layer 38.

Transistor 12 further comprises a region 40. Region 40 covers layer 38 and the central portion of layer 36, that is, the portion which is not covered with layer 38. Region 40 is thus in contact with layer 36. For example, region 40 partially covers the portion 33 of region 30. The lateral walls of region 40 are thus located in front of the portions 33 of region 30.

Region 40 is made of polysilicon. Region 40 is doped with the same conductivity type as regions 22 and 24. Region 40 is, for example, n-type doped. Region 40 forms the emitter of transistor 12.

Transistor 12 comprises a conductive layer 42. Layer 42 covers, preferably entirely, preferably only, the upper surface of region 40. Layer 42 is made of an electrically-conductive material, for example, of a metal. Layer 42 corresponds to the contact of the emitter of transistor 12.

Transistor 12 further comprises spacers 44 (referred to herein as “outer” spacers). Spacers 44 extend on the lateral walls of region 40, preferably on all the lateral walls of region 40. Spacers 44 extend, preferably, vertically from portion 33 to the upper level of region 40. Spacers extend, preferably, horizontally, from the lateral walls of region 40 to the level of the interface between portion 33 and layer 34.

The extrinsic base resistance and the base-collector capacitance are characteristics of bipolar transistors. The maximum oscillation frequency is such that the higher the extrinsic base resistance, the lower the frequency and conversely. Similarly, the maximum oscillation frequency is such that the higher the base-collector capacitance, the lower said frequency and conversely. It may be chosen to increase the doping, for example with boron, of region 30, which would decrease the extrinsic base resistance. However, this would increase the base-collector resistance, in particular due to the diffusion of boron to the collector. The presence of a doping gradient in region 1 enables to decrease the doping at the level of the interface between the collector and the base. The probability of diffusion of boron is thus lower. The maximum oscillation frequency is thus increased.

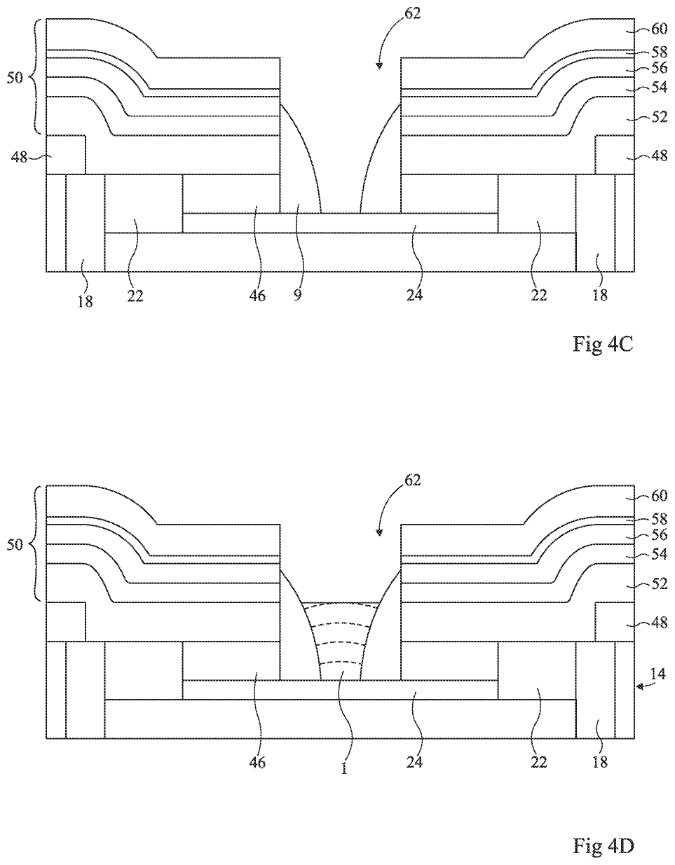

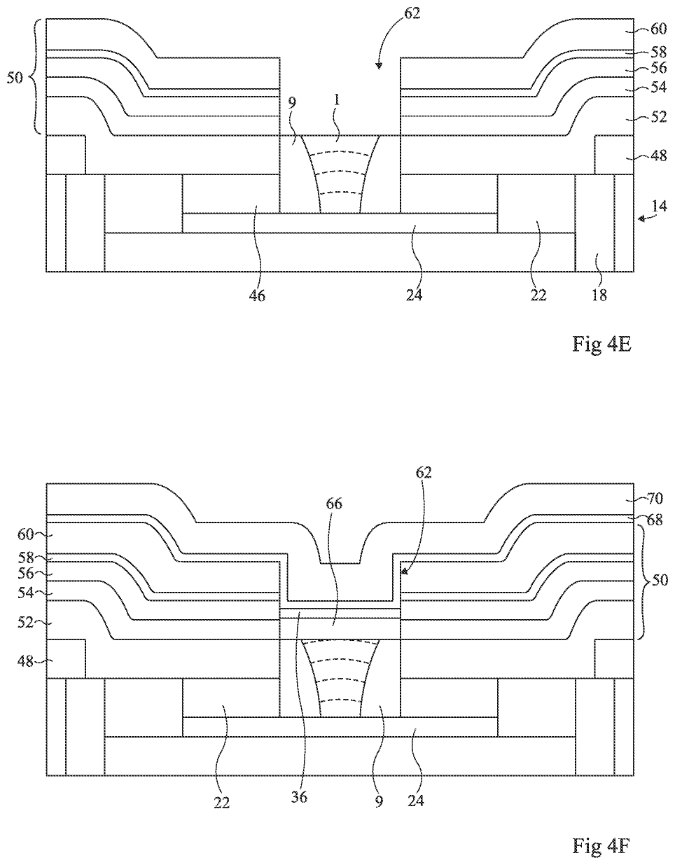

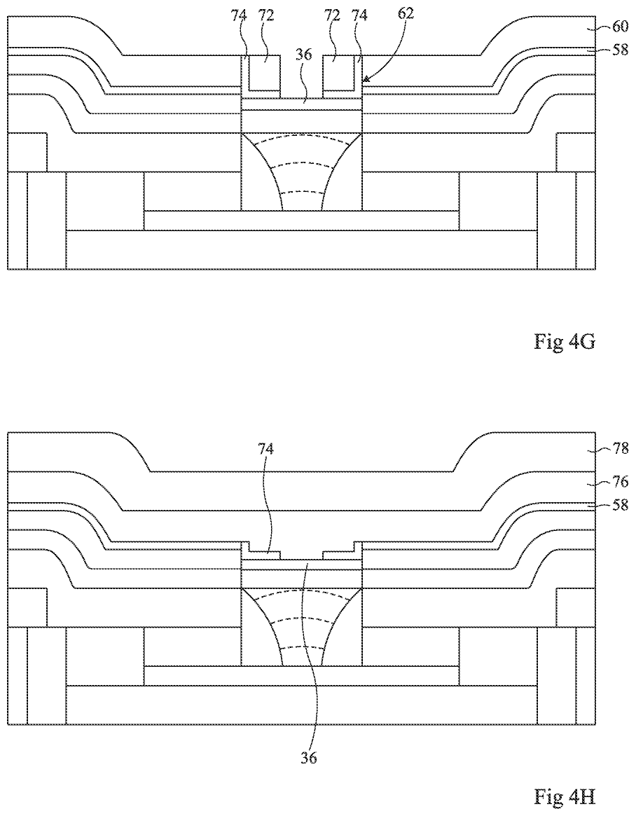

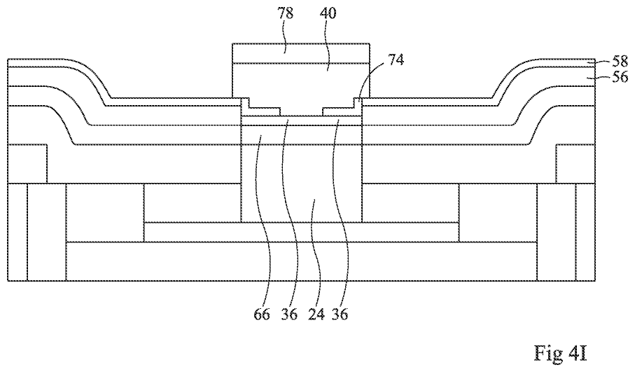

FIGS. 4A to 4I show steps, for example successive, of a method of manufacturing a bipolar transistor such as that shown in FIG. 3.

FIG. 4A shows a device resulting from a step of a method of manufacturing the embodiment of FIG. 3.

During this step, insulating walls 18 are formed in substrate 14. Insulating walls 18 thus delimit an area where the base, the collector, and the emitter of transistor 12 will be formed. The height of walls 18 is smaller than the height of substrate 14. Thus, a portion of substrate 14, not shown, extends under walls 18.

The step of FIG. 4A further comprises the forming of region 22 and of region 24. Regions 22 and 24 are, for example, formed by doping of regions of substrate 14. Regions 22 and 24 are preferably doped to have the doping levels described in relation with FIG. 3.

The step of FIG. 4A comprises the forming of an insulating region 46 in substrate 14. Region 46 is made of the material of region 26, for example of silicon oxide. Region 46 covers, preferably entirely, preferably only, region 24. Thus, region 46 preferably extends from the upper surface of region 24 to the upper level of substrate 14.

FIG. 4B shows a device resulting from another step of the method of manufacturing the embodiment of FIG. 3.

During this step, element 48 are formed. Elements 48 cover, preferably entirely, the locations of regions 22. In other words, elements 48 cover the upper surface of substrate 14 directly around walls 18. Elements 48, for example, at least partially cover walls 18. Elements 48 preferably do not cover regions 22 and region 46.

Elements 48 are, for example, made of a conductive material. Elements 48 are, for example, made of polysilicon. Elements 48 are, for example, made of a non-doped material.

The step of FIG. 4B further comprises the forming of a stack 50 of layers. Stack 50 entirely covers, for example, the structure resulting from the forming of elements 48. In particular, stack 50 covers, preferably entirely, elements 48, the portions of walls 18 not covered with elements 48, regions 22, and region 24.

Stack 50 comprises a lower layer 52. Layer 52 is thus the layer of the stack closest to substrate 14. Layer 52 conformally covers the structure resulting from the forming of elements 48. Layer 52 is made of an insulating material, for example the same material as region 46, for example the same material as the region 26 of FIG. 3. Layer 52 is, for example, made of silicon oxide.

Stack 50 comprises a layer 54 covering layer 52. Layer 54 covers, preferably entirely, preferably conformally, layer 52. Layer 54 is preferably made of the material of region 32. Layer 54 is preferably made of polysilicon. Layer 54 is preferably non-doped. Thus, layer 54 is preferably made of non-doped polysilicon.

Stack 50 comprises a layer 56 covering layer 54. Layer 56 covers, preferably entirely, preferably conformally, layer 54. Layer 56 is made of an insulating material. Layer 56 is made of an insulating material different from the material of layer 52. Layer 56 is, for example, made of silicon nitride.

Stack 50 comprises a layer 58 covering layer 56. Layer 58 covers, preferably entirely, preferably conformally, layer 56. Layer 58 is made of an insulating material. Layer 56 is, for example, made of the same material as layer 52. Layer 56 is made of a material different from the material of layer 56. Layer 56 is, for example, made of silicon oxide.

Stack 50 comprises a layer 60 covering layer 58. Layer 60 covers, preferably entirely, preferably conformally, layer 58. Layer 60 is made of an insulating material. Layer 60 is made of an insulating material different from the material of layer 58. Layer 60 is, for example, made of the same material as layer 56. Layer 60 is, for example, made of silicon nitride.

FIG. 4C shows a device resulting from another step of a method of manufacturing the embodiment of FIG. 3. This step substantially corresponds to the step of FIG. 2B.

During this step, a cavity 62, corresponding to the cavity 8 of FIG. 2B, is formed. Cavity 62 extends from the upper surface of layer 60 to the upper surface of region 24. In other words, the cavity crosses through the layers of stack 50, that is, layers 60, 58, 56, 54, 52, as well as region 46.

Cavity 62 is located at the location of the region 1 and of the spacers 9 of FIG. 3. Thus, the lateral walls of cavity 62 partially correspond to the lateral walls of spacers 9.

The step of FIG. 4C further comprises the forming of spacers 9 in cavity 62. The forming of spacers 9 comprises, for example, the forming, conformally, of a layer made of the material of the spacers, for example over the entire structure resulting from the forming of cavity 62. Said layer is then etched by an anisotropic etching, to only keep spacers 9. A portion of region 24, preferably central, is thus exposed by the etch step.

Spacers 9 cover, preferably entirely, the lateral walls of at least layer 46 and layers 52 and 54. In the example of FIG. 4C, spacers 9 at least partially cover the lateral walls of layers covering layer 52. Thus, spacers 9 cover, for example at least partially, for example entirely, the lateral walls of layer 54 and for example at least partially the lateral walls of layer 56.

FIG. 4D shows a device resulting from another step of a method of manufacturing the embodiment of FIG. 3.

The step of FIG. 4D comprises the epitaxial growth of region 1 from layer 24, more precisely from the portion of the upper surface of layer 24 forming the bottom of cavity 62 and which is not covered with the spacers.

Region 1 extends from region 24 up to the level of the upper surface of layer 52. The height of region 1 is thus smaller than the height along which extend spacers 9 in contact with the lateral walls of cavity 62.

The increasing profile of region 1 from layer 24 causes the decrease of the concentration with the increase of the distance to layer 24 comprising the dopants. The doping of region 1 thus forms a gradient.

FIG. 4E shows a device resulting from another step of a method of manufacturing the embodiment of FIG. 3.

During this step, the portions of spacers 9 extending above the level of the upper surface of region 1 are etched. Thus, the upper surface of region 1 and the upper surface of spacers 9 are substantially coplanar with each other. Further, the upper surface of region 1 and the upper surface of spacers 9 are, preferably, substantially coplanar with the level of the upper surface of layer 52.

In the case where spacers are formed at the step of FIG. 4C to extend up to the level of the upper surface of layer 52, it is possible for this step not to be implemented.

FIG. 4F shows a device resulting from another step of a method of manufacturing the embodiment of FIG. 3.

During this step, a region 66 is formed in cavity 62. Region 66 corresponds to a portion of the region 30 of FIG. 3. Region 66 is, for example, formed by epitaxial growth, from region 1. Region 66 covers, preferably entirely, the upper surface of region 1 and the upper surface of spacers 9 in cavity 62. Region 66 thus fills the bottom of cavity 62 after the forming of the portion of region 1. Region 66 preferably extends from the upper surface of region 1 up to the level of the upper surface of layer 54.

Region 66 is made of the material of the region 30 of FIG. 3. Thus, region 66 is preferably made of n-type doped silicon, in the case of a PNP transistor. The doping level of region 66 is, for example, substantially equal to the doping level of the region 30 of FIG. 3. Alternatively, the transistor may be an NPN transistor, in which case region 66 is P-type doped.

The step of FIG. 4F further comprises the forming of layer 36. Layer 36 is formed on the upper surface of region 66. Layer 36 covers, preferably entirely, preferably only, the upper surface of region 66. Layer 36 is, for example, formed by epitaxial growth. The height of layer 36 is, for example, smaller than the thickness of layer 54.

The step of FIG. 4F comprises the forming of an insulating layer 68. Layer 68 conformally covers the structure resulting from the forming of layer 36. Thus, layer 68 covers the upper surface of layer 60, the lateral walls of cavity 62, that is, the lateral surfaces of layers 60, 58, and 56 located in cavity 62, and the upper surface of layer 36. Layer 68 is thus in contact with the lateral surfaces of layers 60, 58, and 56.

Layer 68 is, for example, made of the same material as layer 58, for example of silicon oxide. The material of layer 68 is different from the material of layer 60.

The step of FIG. 4F comprises the forming of an insulating layer 70. Layer 70 conformally covers the structure resulting from the forming of layer 68. Thus, layer 68 covers, preferably entirely, preferably only, the upper surface of layer 68.

Layer 70 is made of a material different from the material of layer 68. Layer 70 is, for example, made of the same material as layer 60, for example a silicon nitride.

FIG. 4G shows a device resulting from another step of a method of manufacturing the embodiment of FIG. 3.

The step of FIG. 4G comprises a step of anisotropic etching of layer 70. This etch step is preferably configured to only etch layer 70 (i.e., the etch is selective to the material of layer 70). This etch step is, for example, configured not to etch layer 68. Layer 70 is entirely etched during this etch step, except for spacers 72. Spacers 72 are located at the level of the lateral walls of cavity 62. Spacers cover portions 74 of layer 68 having, in cross-section view, an L shape. Spacers 72 do not entirely fill cavity 62. Thus, a central portion of cavity 62 is not covered with spacers 72.

The step of FIG. 4G then comprises a step of etching of layer 68. Layer 68 is preferably entirely etched except for the portions 74 covered with spacers 72. Portions 74 comprise a horizontal portion extending, under spacers 72, on the upper surface of layer 36, from the lateral surfaces of cavity 62 to the center of cavity 62. The horizontal portion of portions 74 are such that a portion, for example a substantially central portion, of the upper surface of layer 36 is not covered with portions 74. Portions 74 further comprise a vertical portion extending on the lateral walls of cavity 62, for example from the upper surface of layer 36 to the upper surface of layer 60.

FIG. 4H shows a device resulting from another step of a method of manufacturing the embodiment of FIG. 3.

The step of FIG. 4H comprises a step of etching of layer 60 and spacers 72. Spacers 72 are made of the same material as layer 60. Spacers 72 and layer 60 can thus be etched by the same etching. The etching is, for example, a wet etching.

During this etch step, the vertical portion of portions 74 is at least partially etched. For example, the vertical portion of portions 74 is etched down to the level of the upper surface of layer 68.

The step of FIG. 4H further comprises the forming of a layer 76 on the structure resulting from the etching of layer 60 and of portions 74. Layer 76 thus covers, preferably entirely, preferably only, layer 58, portions 74 and the portion of layer 36 which is not covered with portions 74.

Layer 76 is made of the material of region 40 of FIG. 1, that is, for example of n-type doped polysilicon. The doping of layer 76 is, for example, substantially equal, for example equal, to the doping of region 40 of FIG. 1.

The step of FIG. 4H further comprises the forming of an insulating layer 78. Layer 78 covers, preferably entirely, preferably only, layer 76. Layer 78 is made of an insulating material, preferably the same material as layer 58, for example silicon oxide.

FIG. 4I shows a device resulting from another step of a method of manufacturing the embodiment of FIG. 3.

During this step, layers 76 and 78 are etched to form region 40 covered with a portion of layer 78. Layers 76 and 78 are, for example, etched simultaneously. Layers 76 and 78 are etched so that the remaining lateral walls of region 40 and of layer 78 are coplanar.

Further, layers 76 and 78 are preferably etched so that portions 74 are entirely covered with region 40. Layers 76 and 78 preferably partially cover layer 58.

The method further comprises additional steps, carried out after the step of FIG. 4I, to obtain the device of FIG. 3. In particular, the method comprises: the removal of the layer 58 which is not covered with region 40; the encapsulation of region 40 in an electrically-insulating region; the partial etching of layers 52 and 54 to partially expose regions 22; the removal of encapsulation layer 80; the forming of spacers 44 on the lateral walls of region 40; the growth of region 66 and the diffusion of the charges to form region 30; and the forming of conductive layers 21, 23, 34, and 42.

According to another embodiment, the stack 50 of FIG. 4B may comprise an additional insulating layer, covering layer 60. The thickness of the additional layer is, for example, substantially equal to the sum of the thicknesses of layer 46 and of layer 52. The step of etching of stack 50 described in relation with FIG. 4C is such that the etching stops at the level of the upper surface of layer 52. Spacers 9 are then formed as described in relation with FIG. 4C. In other words, an insulating layer is formed over the entire structure. Said layer, the additional layer, and layers 46 and 52 are etched, by an anisotropic etching, to form spacers on the walls of cavity 62.

An advantage of the described embodiments is that the base-collector capacitance is smaller than that of a known bipolar transistor. The maximum oscillation frequency is thus higher.

Various embodiments and variants have been described. Those skilled in the art will understand that certain features of these various embodiments and variants may be combined, and other variants will occur to those skilled in the art. In particular, the steps of FIGS. 2A to 2C may be applied to other manufacturing methods, in particular other bipolar transistor manufacturing methods, said methods comprising: the forming of a stack comprising a doped region corresponding to a portion of the collector of the transistor and an insulating layer crossed by a cavity having another portion of the collector formed therein; and the forming of a portion of the base on the other portion of the collector.

Finally, the practical implementation of the described embodiments and variants is within the abilities of those skilled in the art based on the functional indications given hereabove.

1. A method of manufacturing a bipolar transistor, comprising:
forming a collector of the bipolar transistor by:
forming an insulating first layer covering a second layer made of a doped semiconductor material, the second layer forming a first portion of the collector;
forming a cavity crossing through the insulating first layer to reach the second layer;
forming insulating spacers against lateral walls of the cavity; and
epitaxially growing, from the second layer, a first doped semiconductor region in the cavity, the first doped semiconductor region forming a second portion of the collector;
wherein the first doped semiconductor region has a doping concentration decreasing from the second layer.

2. The method according to claim 1, wherein the spacers have a profile decreasing from the second layer.

3. The method according to claim 2, wherein the spacers and the first doped semiconductor region fill the cavity.

4. The method according to claim 1, wherein the first doped semiconductor region comprises a first surface in contact with the second layer, and a second surface opposite to the first surface, the surface area of the second surface being greater than the surface area of the first surface.

5. The method according to claim 4, wherein the surface area of the second surface of the first doped semiconductor region is twice greater than the surface area of the first surface of the first doped semiconductor region.

6. The method according to claim 1, wherein the second layer is formed in a semiconductor substrate, the method further comprising: forming an insulating third layer covering the second layer, and forming a second doped semiconductor region providing part of the collector of the bipolar transistor at a location flush with an upper surface of the substrate.

7. The method according to claim 6, further comprising etching to expose an upper surface of the second doped semiconductor region.

8. The method according to claim 6, further comprising forming a stack of layers over the semiconductor substrate, wherein the stack comprises an insulating fourth layer covering the insulating third layer, a fifth layer made of a material of a base of the bipolar transistor, and an insulating sixth layer, wherein the insulating third and fourth layers form said insulating first layer.

9. The method according to claim 8, wherein the cavity crosses the stack and the insulating third layer to expose the second layer.

10. The method according to claim 9, wherein the insulating spacers at least partially cover lateral walls of the insulating fifth layer, the method further comprising partially etching the insulating spacers so that an upper surface of the insulating spacers is coplanar with an upper surface of the insulating first layer.

11. The method according to claim 1, further comprising forming a seventh layer providing part of a base of the bipolar transistor, wherein the seventh layer covers the first doped semiconductor region.

12. The method according to claim 11, further comprising forming an emitter region over the first doped semiconductor region, wherein the emitter region is separated from the first doped semiconductor region by the seventh layer providing part of the base of the bipolar transistor.

13. A bipolar transistor device, comprising:
an insulating first layer in contact with and covering a second layer made of a doped semiconductor material, said second layer forming a first portion of a collector of the bipolar transistor device;
a cavity crossing through the insulating first layer to reach the second layer;
insulating spacers located against lateral walls of the cavity; and
a first doped semiconductor region in the cavity forming a second portion of the collector of the bipolar transistor device;
wherein the first doped semiconductor region has a doping concentration decreasing from the second layer.

14. The device according to claim 13, wherein a top of the insulating spacers is coplanar with a top of the insulating first layer

15. The device according to claim 13, wherein the insulating spacers have a profile decreasing from the second layer.

16. The device according to claim 13, wherein the insulating spacers and the first doped semiconductor region completely fill the cavity.

17. The device according to claim 13, wherein the first doped semiconductor region comprises a first surface in contact with the second layer, and a second surface opposite to the first surface, a surface area of the second surface being greater than a surface area of the first surface.

18. The device according to claim 17, wherein the surface area of the second surface of the first doped semiconductor region is twice greater than the surface area of the first surface of the first doped semiconductor region.

19. The device according to claim 13, further comprising a layer providing part of a base of the bipolar transistor device, wherein said layer covers the first doped semiconductor region.

20. The method according to claim 19, further comprising an emitter region over the first doped semiconductor region, wherein the emitter region is separated from the first doped semiconductor region by said layer providing part of the base of the bipolar transistor.
